(19) United States
(12) Patent Application Publication
(10) Pub. No.: US 2013/0107654 A1
(43) Pub. Date: May 2, 2013

(54) SEMICONDUCTOR MEMORY APPARATUS, HIGH VOLTAGE GENERATION CIRCUIT, AND PROGRAM METHOD THEREOF

(71) Applicant: In Ho KANG, Icheon-si (KR)

(72) Inventor: In Ho KANG, Icheon-si (KR)

(73) Assignee: HYNIX SEMICONDUCTOR INC., Icheon-si (KR)

(21) Appl. No.: 13/340,795

(22) Filed: Dec. 30, 2011

(30) Foreign Application Priority Data
Oct. 26, 2011 (KR) 10-2011-0110129

(51) Int. Cl. G11C 5/14

(52) U.S. Cl. 365/226

(57) ABSTRACT

A high voltage generation circuit includes: a high voltage generator configured to boost an input voltage and generate first and second high voltages; and a high voltage transmitter configured to drive the first and second high voltages at the same time and generate a selected word line voltage and an unselected word line voltage, during a program mode of a semiconductor memory apparatus.

### CROSS-REFERENCES TO RELATED APPLICATION

The present application claims priority under 35 U.S.C. §119(a) to Korean application number 10-2011-0110129, filed on Oct. 26, 2011, in the Korean Intellectual Property Office, which is incorporated herein by reference in its entirety.

### BACKGROUND

1. Technical Field

The present invention relates generally to a semiconductor integrated circuit, and more particularly to a semiconductor memory apparatus, a high voltage generation circuit, and a program method is thereof.

2. Related Art

A semiconductor memory apparatus may be divided into a volatile memory apparatus and a volatile memory apparatus. The volatile memory apparatus may include a DRAM and the nonvolatile memory apparatus may include a flash memory apparatus such as a NAND-type flash memory apparatus. The semiconductor memory apparatus includes a plurality of memory cells. For example, the NAND-type flash memory apparatus includes a plurality of memory cells which share a drain or source and are coupled in series to form a cell string. Therefore, the NAND-type flash memory apparatus may store large-volume data.

In order for the flash memory apparatus to store information, that is, to program data, a high voltage is applied to write data in a memory cell and a verify process is performed so as to verify whether desired data was written or not. A time required for programming data into a memory cell is referred to as a unit time, and the unit time may include a time required for applying a high voltage to a word line, in addition to the data program and verify time.

### SUMMARY

In one embodiment of the present invention, a high voltage generation circuit includes: a high voltage generator configured to boost an input voltage and generate first and second high voltages; and a high voltage transmitter configured to drive the first and second high voltages at the same time and generate a selected word line potential and an unselected word line potential, during a program mode of a semiconductor memory apparatus.

In another embodiment of the present invention, a semiconductor memory apparatus includes: a memory cell block including a plurality of memory cells coupled between a word line and a bit line; a block switch configured to couple a global word line to the word line; a block decoder configured to drive the block switch; and a high voltage generation circuit configured to generate first and second voltages by boosting an input voltage, generate a selected word line potential and an unselected word line potential by simultaneously driving the first and second voltages in response to a program command, and apply the selected word line potential and the unselected word line potential to the global word line.

In another embodiment of the present invention, a program method of a semiconductor memory apparatus includes the steps of: generating first and second high voltages in response to a program command; generating a selected word line potential by driving the first and second high voltages at the same time, and applying the selected word line potential to a global word line switch; and generating an unselected word line potential by driving the first and second high voltages at the same time, and applying the unselected word line potential to the global word line switch.

### BRIEF DESCRIPTION OF THE DRAWINGS

Features, aspects, and embodiments are described in conjunction with the attached drawings, in which:

FIG. 1 is a configuration diagram of a semiconductor memory apparatus according to an embodiment of the present invention;

FIG. 2 is a diagram explaining voltage level change during a program operation of a semiconductor memory apparatus according to an embodiment of the present invention;

FIG. 3 is a configuration diagram of a high voltage generation circuit according to an embodiment of the present invention;

FIG. 4 is a configuration diagram of a high voltage transmitter of FIG. 3;

FIG. 5 is a diagram explaining voltage level change during a program operation in the semiconductor memory apparatus according to an embodiment of the present invention; and

FIG. 6 is a configuration of a semiconductor memory apparatus according to an embodiment of the present invention.

### DETAILED DESCRIPTION

Hereinafter, a semiconductor memory apparatus, a high voltage generation circuit, and a program method thereof according to the present invention will be described below with reference to the accompanying drawings through exemplary embodiments.

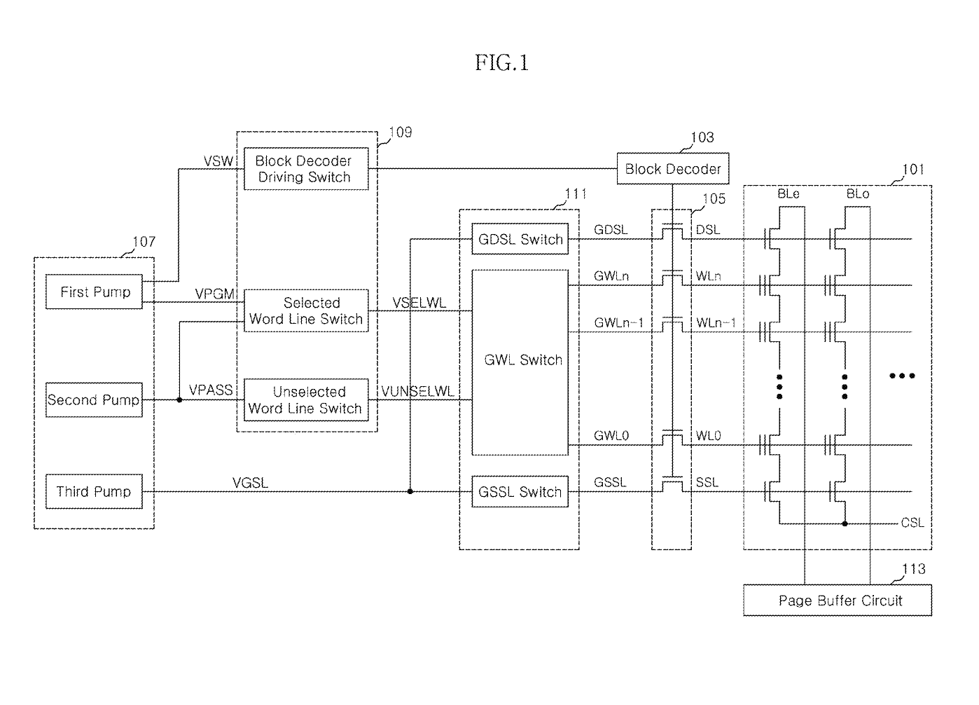

FIG. 1 is a configuration diagram of a semiconductor memory apparatus according to an embodiment of the present invention.

Referring to FIG. 1, the semiconductor memory apparatus includes a memory cell block 101, a block decoder 103, a block switch 105, a high voltage generator 107, a high voltage transmitter 109, a global line selector 111, and a page buffer circuit 113.

The memory cell block 101 includes a plurality of memory cells coupled in series between word lines WL and bit lines BL. This may be referred to as a string structure. In particular, (n+1) memory cells are coupled in series to a drain select switch driven by a signal applied to a drain select line DSL, thereby forming a string, and the last memory cell of the string is coupled to a source select switch driven by a signal applied to a source selection line SSL. Furthermore, a plurality of memory cells coupled to a word line WL form a page.

The block decoder 103 is configured to generate a block select signal to control the block switch 105. The block switch 105 is configured to apply a voltage signal generated by the high voltage generator 107 to the memory cell block 101 according to the block select signal generated by block decoder 103. For this operation, the block switch 105 includes switches configured to couple global word lines GWL to the memory cell block 101 and switches configured to couple a global drain select line GDSL and a global source select line GSSL, respectively, to the memory cell block 101.

The high voltage generator 107 includes a plurality of pumps, for example, first to third pumps. Furthermore, each of the pumps is configured to provide a high voltage for each operation mode of the semiconductor memory cell.

More specifically, a third high voltage VSW generated from the first pump is provided to the block decoder 103 through a block decoder driving switch of the high voltage transmitter 109. Furthermore, a first high voltage VPGM generated from the first pump is provided to a selected word line switch of the high voltage transmitter 109, and a second high voltage VPASS generated from the second pump is provided to the selected word line switch and an unselected word line switch of the high voltage transmitter 109. Furthermore, a fourth high voltage VGSL generated from the third pump is provided to a global drain line select switch and a global source line select switch of the global line selector 111.

As the first and second high voltages VPGM and VPASS are provided to the selected word line switch and the second high voltage VPASS is provided to the unselected word line switch, the unselected word line switch drives the global word line switch. Furthermore, the high voltage is applied to a corresponding word line through a switch which is turned on by the control of the block decoder 103.

As such, the semiconductor memory apparatus includes the high voltage generator 107 to pump a voltage required for each operation mode of the semiconductor memory apparatus, and provides a proper high voltage to the memory cell block 101 through the high voltage transmitter 109 or the global line selector 101.

As described above, the program operation of the semiconductor memory apparatus includes a program operation and a verify operation. In general, the semiconductor memory apparatus perform a program operation according to an incremental-step-pulse programming (ISPP) method. During the verify operation, If a word line has been determined as ‘pass’, the word line is unselected in subsequent program operations and receives an unselected word line voltage. Also, during the verify operation, a read voltage (i.e., a voltage for verification) is supplied to a selected word line to read and determine the level of data stored in a memory cell. Furthermore, after the verify operation, a word line coupled to a memory cell determined as ‘pass’ is unselected and receives an unselected word line voltage so that a program operation is not performed on the memory cell, and a word line coupled to a memory cell in which desired-level data is not written is selected and applied with a program voltage, thereby performing a programming operation again.

Therefore, as the program operation is repeated, the number of unselected word lines inevitably increases. As shown in FIG. 1, the pass voltage generated from the second pump is distributed and supplied to the selected word line switch as well as the unselected word line switch. Therefore, it takes a large amount of time to precharge a word line to a desired level for the program operation.

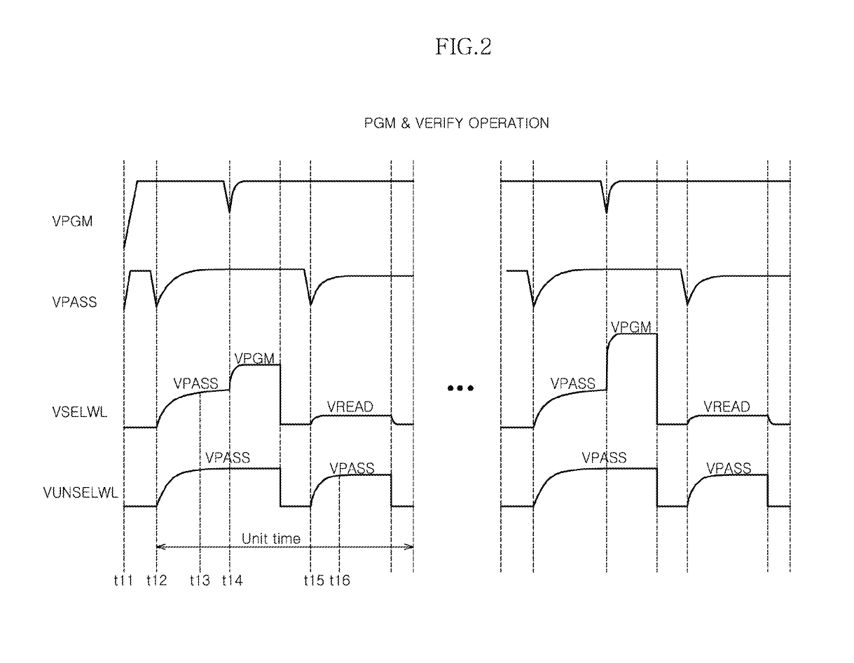

FIG. 2 is a diagram explaining voltage level change during the program operation of a semiconductor memory apparatus according to an embodiment of the present invention.

Before the program operation is started (i.e., t11 to t12), the first high voltage, that is, the program voltage VPGM and the second high voltage, that is, the pass voltage VPASS are generated at the same level.

After the program operation is started (i.e., after t12), the program voltage VPGM is supplied to a selected word line, and the pass voltage VPASS is distributed and supplied to the selected word line and an unselected word line.

Therefore, it can be seen that a time t12 to t13 required until the voltage VSELWL of the selected word line is stabilized to the pass voltage level VPASS and a time t12 to t13 required until the voltage VUNSELWL of the unselect word line receiving the pass voltage VPASS is stabilized to the pass voltage level VPASS are long.

After the voltage VSELWL of the selected word line and the voltage VUNSELWL of the unselected word line are stabilized to the target levels VPGM and VPASS (i.e., t14), a program operation is performed, and a verify operation is then performed.

During the verify operation (i.e., t15), a read voltage VREAD is applied to the selected word line, and the pass voltage VPASS is applied to the unselected word line. However, since the unselected word line select switch is driven only by the second high voltage VPASS, a large amount of time is required until the unselected word line rises to the pass voltage level (i.e., t15 to t16).

During the program operation, precharging the respective word lines to the target levels may serve as a factor which decides the unit time. Therefore, there is a demand for a method capable of precharging a word line at high speed.

Accordingly, a method for increasing the drivability of the second pump for generating the pass voltage may be considered. However, in order to increase the drivability of the second pump, the size of a pumping capacitor may increase. In this case, the chip size may increase.

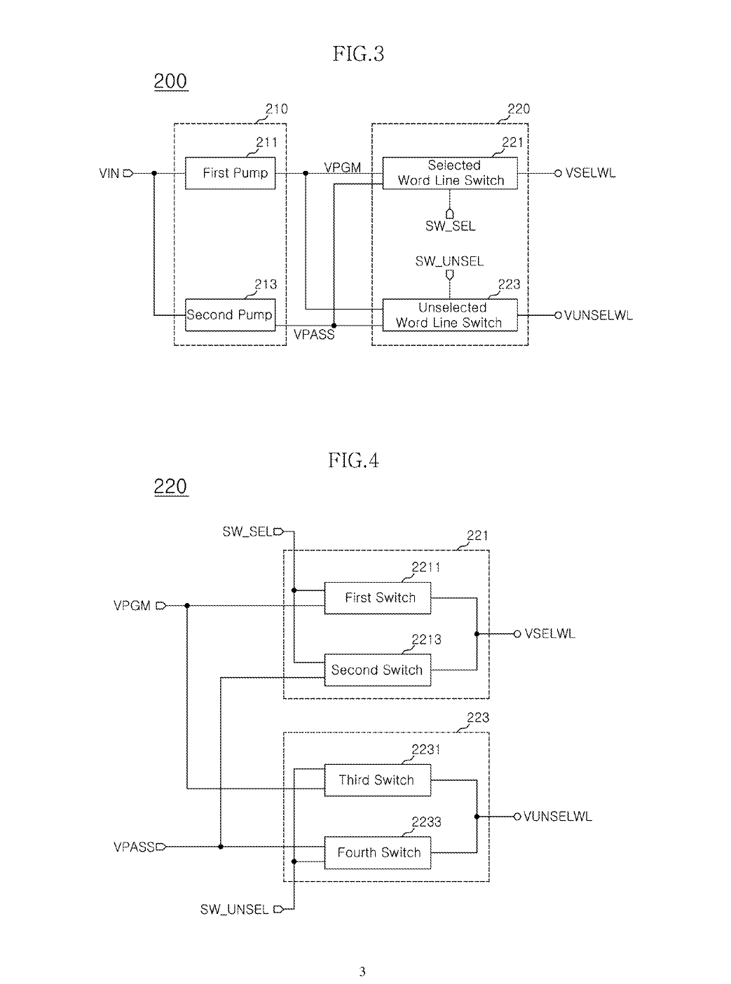

FIG. 3 is a configuration diagram of a high voltage generation circuit according to an embodiment of the present invention.

Referring to FIG. 3, the high voltage generation circuit 200 according to an embodiment of the present invention includes a high voltage generator 210 and a high voltage transmitter 220.

The high voltage generator 210 includes a first pump 211 and a second pump 213. The first pump 211 is configured to boost an input voltage VIN and generate a first voltage, for example, a program voltage VPGM. The second pump 213 is configured to boost the input voltage VIN and generate a second voltage, for example, a pass voltage VPASS.

The high voltage transmitter 220 includes a selected word line switch 221 and an unselected word line switch 223. The selected word line switch 221 is configured to be switched on so as to pass the first and second voltages VPGM and VPASS, for example, at the same time and generate a selected word line voltage VSELWL in response to a word line select signal SW_SEL, and the unselected word line switch 223 is configured to be switched on so as to pass the first and second voltages VPGM and VPASS, for example, at the same time and generate an unselected word line voltage VUNSELWL in response to the word line unselected signal SW_UNSEL.

According to an embodiment of the present invention, the voltage of the first pump 211 as well as the voltage of the second pump 213 is also used as an input voltage of the unselected word line switch 223. Therefore, since the total drivability of the first and second pumps 211 and 213 is greater than that of a single pump, a time required for precharging a word line may decrease.

FIG. 4 is a configuration diagram of the high voltage transmitter of FIG. 3.

Referring to FIG. 4, the selected word line switch 221 of the high voltage transmitter 220 includes a first switch 2211 and a second switch 2213. The first switch 2211 is configured to be switched on so as to pass the first high voltage VPGM in response to the word line select signal SW_SEL. The second switch 2213 is configured to be switched on so as to pass the second high voltage VPASS in response to the word line select signal SW_SEL.

Furthermore, the unselected word line switch 223 includes a third switch 2231 and a fourth switch 2233. The third switch 2231 is configured to be switched on so as to pass the first high voltage VPGM in response to the word line unselect signal SW_UNSEL. The fourth switch 2233 is configured to be switched on so as to pass the second high voltage VPASS in response to the word line unselect signal SW_UNSEL.

In an embodiment of the present invention, the unselected word line switch 223 includes the third switch 2231 for passing the first high voltage VPGM in addition to the switch for passing the second high voltage VPASS, that is, the fourth switch 2233, so that the unselected word line voltage VUNSELWL is generated by the first and second high voltages VPGM and VPASS.

Therefore, since the unselected word line switch 223 may be driven to a large drivability without increasing the drivability of the second pump 213, the word line may be precharged to a desired level at high speed.

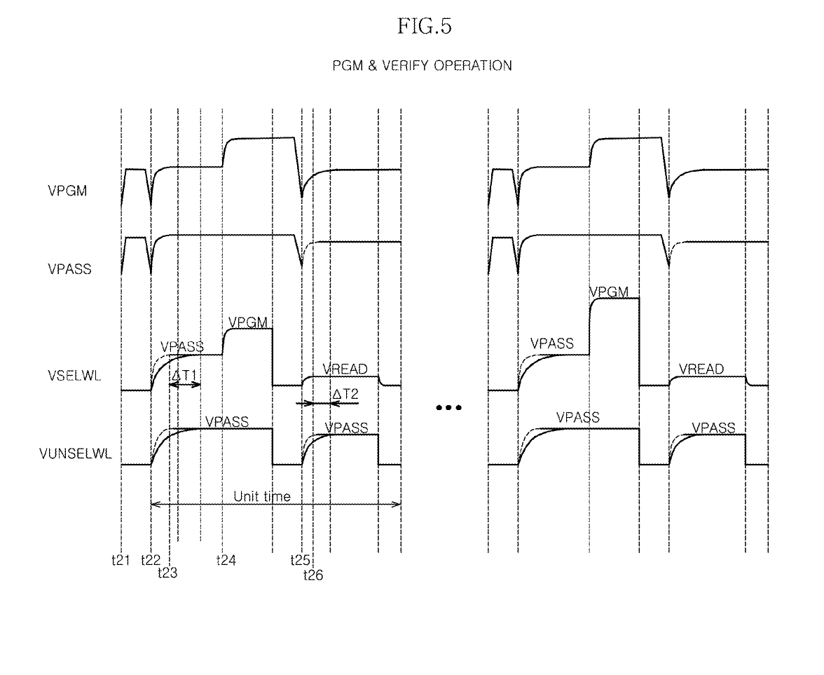

FIG. 5 is a diagram explaining voltage level change during a program operation in the semiconductor memory apparatus according to an embodiment of the present invention.

Before the program operation is started (i.e., t21 to t22), the first high voltage, that is, the program voltage VPGM, and the second high voltage, that is, the pass voltage VPASS are generated at the same level.

After the program operation is started (i.e., after t22), the program voltage VPGM and the pass voltage VPASS are supplied to a selected word line and an unselected word line.

Therefore, it can be seen that a time t22 to t23 required until the voltage VSELWL of the selected word line is stabilized to the pass voltage level VPASS and a time t22 to t23 required until the voltage VUNSELWL of the unselected word line is stabilized to the pass voltage level VPASS are reduced by a time ΔT1.

After the voltage VSELWL of the selected word line and the voltage VUNSELWL of the unselected word line are stabilized to the target levels VPGM and VPASS (i.e., t24), the program operation is started, and a verify operation is then started.

During the verify operation (i.e., t25), a read voltage VREAD is applied to the selected word line, and the pass voltage VPASS is applied to the unselected word line. Even at this time, since the unselected word line selection switch is driven to a large drivability by the first and second high voltages VPGM and VPASS, the voltage of the unselected word line may rapidly rise to the pass voltage level VPASS (i.e., t25 to t26). Accordingly, it can be seen that a time t25 to t26 required until the voltage VUNSELWL of the unselected word line is stabilized to the pass voltage level VPASS is reduced by a time ΔT2.

As a result, the unit program time may be reduced to operate the semiconductor memory apparatus at high speed.

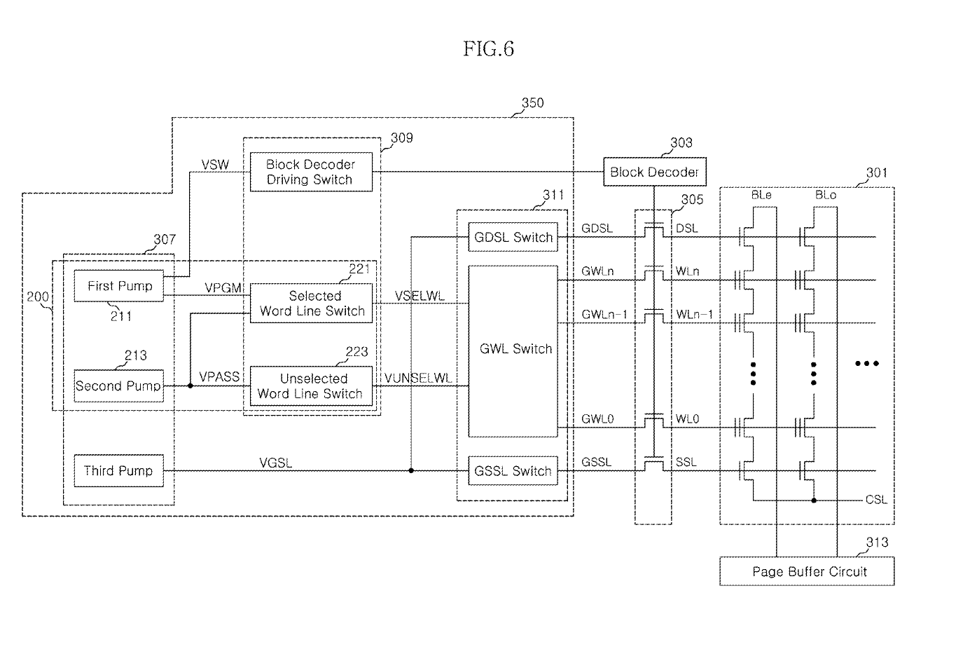

FIG. 6 is a configuration of a semiconductor memory apparatus according to an embodiment of the present invention.

Referring to FIG. 6, the semiconductor memory apparatus 300 according to an embodiment of the present invention includes a memory cell block 301, a block decoder 303, a block switch 305, a high voltage generation circuit 350, and a page buffer circuit 313. Furthermore, the high voltage generation circuit 350 may include a high voltage generator 307, a high voltage transmitter 309, and a global line selector 311.

The memory cell block 301 may include a semiconductor memory cell block, for example. The memory cell block 301 may includes a plurality of memory cells coupled in a string structure between word lines WL and bit lines BL.

The block decoder 303 is configured to generate a block select signal to control the block switch 305. Furthermore, the block switch 305 is configured to apply a voltage signal generated by the high voltage generation circuit 350 to the memory cell block 301 according to the block select signal generated by the block decoder 303.

The block switch 305 may include switches configured to couple global word lines GWL to the memory cell block 301 and switches configured to couple a global drain select line GDSL and a global source select line GSSL to the memory cell block 301.

In addition, the high voltage generation circuit 350 may include the high voltage generator 307, the high voltage transmitter 309 and the global line selector 311. The high voltage generator 307 includes a plurality of pumps. The high voltage transmitter 309 is configured to provide a high voltage generated by the high voltage generator 307 to the block decoder 303 or the global line selector 311. The global line selector 311 is configured to provide the high voltage provided by the high voltage transmitter 309 to the memory cell block 301 through the block switch 305.

More specifically, the high voltage generator 307 includes a plurality of pumps, for example, first to third pumps. Each of the pumps is configured to provide a high voltage for each operation mode of the memory cell block 301. For example, a third high voltage generated from the first pump 211 is provided to the block decoder 303 through a block decoder driving switch of the high voltage transmitter 309. Furthermore, a first high voltage VPGM generated from the first pump 211 is provided to a selected word line switch of the high voltage transmitter 309, and a second high voltage VPASS generated from the second pump 213 is provided to the selected word line switch and an unselected word line switch of the high voltage transmitter 309. Furthermore, a fourth high voltage VGSL generated from the third pump is provided to a global drain select line switch and a global source line select switch of the global line selector 311.

In the semiconductor memory apparatus 300 according to an embodiment of the present invention, the first pump 211, the second pump 213, the selected word line switch 221, and the unselected word line switch 223 may be configured in such a manner as illustrated in FIGS. 3 and 4.

In this case, the first high voltage VPGM generated from the first pump 211 and the second high voltage VPASS generated from the second pump 213 are supplied to the selected word line switch 221, and the first high voltage VPGM generated from the first pump 211 and the second high voltage VPASS generated from the second pump 213 are supplied to the unselected word line switch 223.

That is, since the unselected word line switch 223 as well as the selected word line switch 221 is driven by a high voltage obtained by adding the pass voltage and the program voltage, a word line is driven with a large drivability during the program operation, and thus the voltage of the word line rises to a target level at high speed.

When the precharge time of the word line is reduced during the program mode, it means that the unit program time may be reduced. Accordingly, it is possible to improve the operation speed of the semiconductor memory apparatus.

Therefore, it is possible to improve the drivability of the word line without increasing the size of capacitors composing the pumps.

While certain embodiments have been described above, it will be understood to those skilled in the art that the embodiments described are by way of example only. Accordingly, the apparatus and method described herein should not be limited based on the described embodiments. Rather, the apparatus and method described herein should only be limited in light of the claims that follow when taken in conjunction with the above description and accompanying drawings.

What is claimed is:

1. A high voltage generation circuit comprising:
a high voltage generator configured to boost an input voltage and generate first and second high voltages; and
a high voltage transmitter configured to drive the first and second high voltages at the same time and generate a selected word line voltage and an unselected word line voltage, during a program mode of a semiconductor memory apparatus.

2. The high voltage generation circuit according to claim 1, wherein the high voltage generator comprises:
a first pump configured to generate the first high voltage by boosting the input voltage; and
is a second pump configured to generate the second high voltage by boosting the input voltage.

3. The high voltage generation circuit according to claim 2, wherein the high voltage transmitter comprises:
a selected word line switch configured to be switched on so as to pass the first and second high voltages at the same time and generate the selected word line voltage; and
an unselected word line switch configured to be switched on so as to pass the first and second high voltages at the same time and generate the unselected word line voltage.

4. The high voltage generation circuit according to claim 3, wherein the selected word line switch comprises:
a first switch configured to be switched on so as to pass the first high voltage in response to a word line select signal; and
a second switch configured to be switched on so as to pass the second high voltage in response to the word line select signal.

5. The high voltage generation circuit according to claim 3, wherein the unselected word line switch comprises:
a third switch configured to be switched on so as to pass the first high voltage in response to a word line unselect signal; and
a fourth switch configured to be switched on so as to pass the second high voltage in response to the word line unselect signal.

6. A semiconductor memory apparatus comprises:
a memory cell block comprising a plurality of memory cells coupled between a word line and a bit line;
a block switch configured to couple a global word line to the word line;
a block decoder configured to drive the block switch; and
a high voltage generation circuit configured to generate first and second voltages by boosting an input voltage, generate a selected word line voltage and an unselected word line voltage by simultaneously driving the first and second voltages in response to a program command, and apply the selected word line voltage and the unselected word line voltage to the global word line.

7. The semiconductor memory apparatus according to claim 6, wherein the high voltage generation circuit comprises:
a first pump configured to generate the first high voltage; and
a second pump configured to generate the second high voltage.

8. The semiconductor memory apparatus according to claim 6, wherein the high voltage generation circuit further comprises a high voltage transmitter, and
the high voltage transmitter comprises:
a selected word line switch configured to generate the selected word line voltage by passing the first and second high voltages at the is same time; and
an unselected word line switch configured to generate the unselected word line voltage by passing the first and second high voltages the same time.

9. A program method of a semiconductor memory apparatus, comprising the steps of:
generating first and second high voltages in response to a program command;
generating a selected word line voltage by driving the first and second high voltages at the same time, and applying the selected word line voltage to a global word line switch; and
generating an unselected word line voltage by driving the first and second high voltages at the same time, and applying the unselected word line voltage to the global word line switch.

10. The program method according to claim 9, wherein the first and second high voltages are independently generated.

11. The program method according to claim 9, wherein the selected word line voltage and the unselected word line voltage are independently generated.
